(19) United States
(12) Patent Application Publication
(10) Pub. No.: US 2004/0161937 A1
(43) Pub. Date: Aug. 19, 2004

(54) Polishing composition and polishing method using same

(76) Inventors: Hiroshi Asano, Gifu-ken (JP); Tetsuji Hori, Aichi-ken (JP)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 10/776,783

(22) Filed: Feb. 11, 2004

(30) Foreign Application Priority Data
Feb. 12, 2003 (JP) 2003-034212

(51) Int. Cl. H01L 21/302; H01L 21/461

(52) U.S. Cl. 438/691; 438/690

(57) ABSTRACT

The present invention relates to a polishing composition more suitable for application in polishing semiconductor devices. The polishing composition consists of a liquid component including water and water-soluble amine. The water-soluble amine includes at least one of triethylenetetramine (TETA) and tetraethylenepentamine (TEPA) and is dissolved in the water.

### BACKGROUND OF THE INVENTION

The present invention relates to a polishing composition used in applications such as for polishing a semiconductor device, and a polishing method using such a polishing composition.

The wiring of a semiconductor device is formed, for example with reference to FIG. 1, as follows: First, a semiconductor substrate is prepared. The substrate has an insulating film 11 consisting of silicon dioxide. A trench 12 having a predetermined pattern is formed on the surface of the insulating film 11, and thereafter, a conductive film 13 consisting of polycrystalline silicon is formed on the insulating film 11. Next, an outer portion, which is the part of the conductive film 13 located outside the trench 12, is removed using chemical mechanical polishing. Thereby, as FIG. 2 shows, only an inner portion, which is the part of the conductive film 13 located inside the trench 12, is left on the insulating film 11, and functions as the wiring.

In order to polish a semiconductor device to remove the outer portion, conventionally, a polishing composition containing solid components, i.e., components present in solid state in the polishing composition, such as colloidal silica and fumed silica has been used. Such polishing compositions are disclosed in, for example, U.S. Pat. No. 4,169,337 and Japanese Laid-Open Patent Publication No. 10-321569.

However, in the case of conventional polishing compositions containing solid components, the semiconductor devices may be scratched by the solid components for mechanically polishing the objects to be polished, or the solid components in the polishing compositions may remain on the semiconductor devices after polishing. These may induce electrical defects in the semiconductor devices, such as breakage of wires, resistance failures, and insulation failures. In addition, the separation of solid components from liquid components is required before disposing of the polishing compositions after use.

### SUMMARY OF THE INVENTION

Accordingly, it is an objective of the present invention to provide a polishing composition more suitable for the application of polishing a semiconductor device, and a polishing method using such a polishing composition. Another objective of the present invention is to provide a method for manufacturing a semiconductor device using such a polishing composition.

To achieve the foregoing and other objectives and in accordance with the purpose of the present invention, a polishing composition is provided. The polishing composition is for polishing an object having a portion including silicon dioxide and a portion conductive film including polycrystalline silicon. The polishing composition consists of a liquid component including water and water-soluble amine. The water-soluble amine comprises at least one of triethylenetetramine and tetraethylenepentamine and is dissolved in the water.

In another aspect of the present invention, a polishing method is provided. The method is for polishing an object having an insulating film including silicon dioxide and a conductive film including polycrystalline silicon. The insulating film has a surface including a trench. The conductive film is located on the insulating film and has an inner portion located inside the trench and an outer portion located outside the trench. The method includes the steps of: preparing a polishing composition, wherein the polishing composition consists of a liquid component including water and water-soluble amine, and wherein the water-soluble amine comprises at least one of triethylenetetramine and tetraethylenepentamine and is dissolved in the water; and polishing the object using the polishing composition to remove the outer portion of the conductive film.

Also, the present invention provides a method for manufacturing a semiconductor device. The method includes the steps of: preparing a polishing composition, wherein the polishing composition consists of a liquid component including water and water-soluble amine, and wherein the water-soluble amine comprises at least one of triethylenetetramine and tetraethylenepentamine and is dissolved in the water; preparing a semiconductor substrate having an insulating film including silicon dioxide; forming a trench on the surface of the insulating film; forming a conductive film including polycrystalline silicon on the insulating film to prepare an object having the insulating film and the conductive film, with the conductive film located on the insulating film and having an inner portion located inside the trench and an outer portion located outside the trench; and polishing the object using the polishing composition to remove the outer portion of the conductive film.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a sectional view schematically showing part of a semiconductor device in the process for forming wiring; and

FIG. 2 is a sectional view schematically showing part of a semiconductor device after forming wiring.

### DETAILED DESCRIPTION OF THE PREFERRED EMBODIMENTS

One embodiment of the present invention will now be described.

The polishing composition according to the embodiment consists of either triethylenetetramine (TETA) or tetraethylenepentamine (TEPA), and water. Both TETA represented by the following formula (1) and TEPA represented by the following formula (2) are water-soluble, and are dissolved in said water in the polishing composition. Therefore, the polishing composition does not contain solid components, but only liquid components.

H₂N(CH₂CH₂NH)₂CH₂CH₂NH₂ (1)

H₂N(CH₂CH₂NH)₃CH₂CH₂NH₂ (2)

TETA and TEPA play a role to chemically polish the object to be polished. The polishing composition containing TETA and TEPA has a high ability to polish polycrystalline silicon, but has a low ability to polish silicon dioxide. In other words, when the ratio of the ability to polish polycrystalline silicon to the ability to polish silicon dioxide is defined as the selection ratio, the polishing composition containing TETA and TEPA is said to have a high selection ratio. The ability of a specific polishing composition to polish an object is generally measured as the quantity of the object that is polished per unit time.

The selection ratio of the polishing composition according to the present embodiment is preferably 100 or more. A polishing composition having a selection ratio of 100 or more is particularly suitable for applications for polishing semiconductor devices. However, the preparation of a polishing composition having a selection ratio that exceeds 1500 is technically difficult.

When a polishing composition contains TETA, the quantity of TETA contained in the polishing composition is preferably 0.001 to 10% by weight, and more preferably 0.1 to 5.0% by weight. When a polishing composition contains TEPA, the quantity of TEPA contained in the polishing composition is preferably 0.001 to 10% by weight, and more preferably 1 to 10% by weight. If the content of TETA or TEPA is as low as or less than 0.001% by weight, the polishing ability of the polishing composition is not so high. If a polishing composition contains as large as quantity of TETA or TEPA that is more than 10% by weight, the disposal thereof is not easy. This is because the total organic carbon (TOC) or chemical oxygen demand (COD) in the polishing composition after use is difficult to lower to standard levels.

The water in the polishing composition preferably contains as little impurities as possible, and specifically, distilled water, pure water, or ultra-pure water is preferable.

The quantity of water contained in the polishing composition is preferably 90 to 99.998% by weight. If the content of water in a polishing composition is less than 90% by weight, the polishing composition inevitably contains a large quantity of TETA or TEPA, and therefore, the disposal thereof is not easy. If the content of water in a polishing composition is more than 99.998% by weight, the polishing composition inevitably contains a small quantity of TETA or TEPA, and therefore, the polishing ability thereof is not so high.

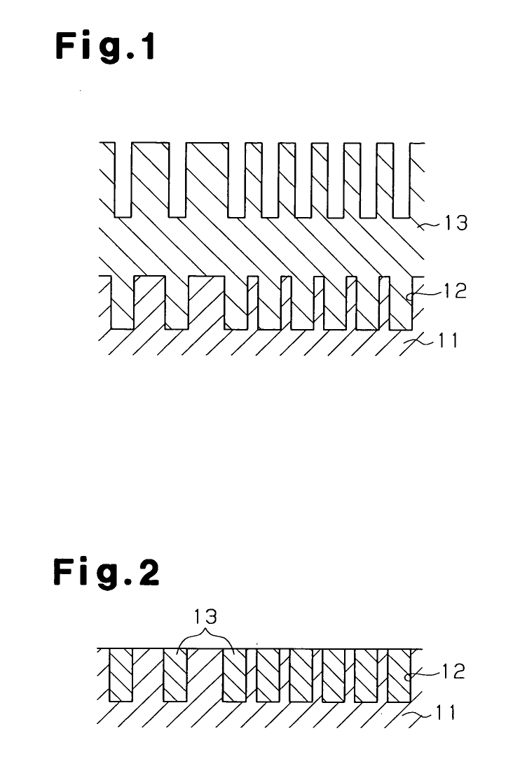

The polishing composition according to the present embodiment is used in applications for polishing, for example, semiconductor devices. More specifically, in the semiconductor device in the process of forming wiring thereon shown in FIG. 1, the polishing composition is used in chemical mechanical polishing for removing an outer portion, which is the part of the conductive film 13 located outside the trench 12. This type of polishing is normally performed in a state where a semiconductor device and a polishing pad are compressed against each other with a constant pressure, while rotating the semiconductor device and the polishing pad in directions opposite to each other and while supplying a polishing composition to the polishing pad. The thickness of the conductive film 13 before polishing is normally 2000 to 6000 Å. Although the time required to remove the outer portion using the polishing composition depends on the specific conditions, it is normally about 2 minutes.

The pressure for compressing the semiconductor device against the polishing pad, that is the polishing pressure, is preferably 3.5 to 58 kPa (about 35 to about 600 g/cm²). If the polishing pressure is lower than 3.5 kPa, the semiconductor device is not well polished. If polishing is performed under a polishing pressure exceeding 58 kPa, not only the outer portion, but also an inner portion, which is the part of the conductive film 13 located inside the trench 12, is polished, and a phenomenon known as dishing may occur.

The relative linear speed between the semiconductor device and the polishing pad during polishing is preferably 30 to 100 m/min. If the relative linear speed is as low as or less than 30 m/min, the semiconductor device is not well polished, and dishing may occur. If the relative linear speed exceeds 100 m/min, the polishing composition is not held on the polishing pad due to large centrifugal force, and the semiconductor device is also not well polished. In addition, it is difficult to control the polishing speed to be constant.

The present embodiment provides the following advantages.

The polishing compositions according to the embodiment consist only of liquid components, and do not contain any solid components. Therefore, no defects of the semiconductor device occurs from solid components contained in the polishing composition. Furthermore, since there is no need to separate the polishing composition after use into solid components and liquid components, it can be disposed of easily. Therefore, the polishing composition according to the present embodiment is most suitable for applications for polishing semiconductor devices.

When the content of TETA or TEPA in the polishing composition is 0.001 to 10% by weight, the polishing composition has sufficient polishing ability, and the polishing composition after use becomes further readily disposable.

When the ratio of the ability to polish polycrystalline silicon to the ability to polish silicon dioxide is 100 or more, the polishing composition is particularly suitable for applications for polishing semiconductor devices. If the ratio is less than 100, the insulating film 11 (silicon dioxide) may be excessively polished, or the conductive film 13 (polycrystalline silicon) may be poorly polished.

It should be apparent to those skilled in the art that the present invention may be embodied in many other specific forms without departing from the spirit of scope of the invention. Particularly, it should be understood that the invention may be embodied in the following forms.

The polishing composition may contain both TETA and TEPA. In this case, the total of the content of TETA and the content of TEPA combined is preferably 0.001 to 10% by weight.

The polishing composition may contain components other than TETA, TEPA, and water. However, the components cannot be present in a solid state in the polishing composition, and is preferably water-soluble or water dispersible. The examples of such components include surface-active agents.

The polishing composition may be prepared immediately before use by diluting a previously prepared stock solution with water, or may be prepared immediately before use by mixing water with the components other than the water.

In polishing the semiconductor device shown in FIG. 1, after part of the outer portion of the conductive film 13 is removed by a method different from polishing using the polishing composition according to the present embodiment, the remaining part of the outer portion may be removed by polishing using the polishing composition according to the present embodiment. The method for first removing part of the outer portion may be chemical mechanical polishing using a polishing composition containing solid components such as colloidal silica, or may employ other methods. The surface of the conductive film 13 formed on the insulating film 11 consists normally of silicon dioxide formed by oxidation of polycrystalline silicon by oxygen in the air. Since the ability of the above-described polishing composition according to the embodiment to polish silicon dioxide is not high, it is especially preferable to remove the outer portion following the above-described procedures in the case where the surface of the conductive film 13 is oxidized. The method for removing silicon dioxide on the surface of the conductive film 13 may be chemical mechanical polishing using a polishing composition containing solid components such as colloidal silica, or may be a method for dissolving the silicon dioxide using hydrofluoric acid.

In order to prevent oxidation on the surface of the conductive film 13 formed on the insulating film 11, the semiconductor device after forming the conductive film 13 formed on the insulating film 11 may be held in a nitrogen atmosphere, or under a reduced pressure. Alternatively, the surface of the conductive film 13 may be covered with a masking tape or the like.

In order to improve the electrical properties of the conductive film 13, a dopant, such as antimony, may be introduced into the conductive film 13 by ion implantation.

Next, the present invention will be described further specifically referring to examples and comparative examples.

### EXAMPLES 1 TO 25

In Examples 1 to 22, TETA or TEPA was dissolved in water to prepare polishing compositions. In Examples 23 to 25, TETA and TEPA was dissolved in water to prepare polishing compositions. The contents of TETA and TEPA in each polishing composition in Examples 1 to 25 are shown in the “Water-soluble amine” column of Table 1 below.

The “Polishing speed” column of Table 1 shows the polishing speeds when polycrystalline silicon (poly-Si) and silicon dioxide (SiO₂) are polished using each of the polishing compositions of Examples 1 to 25. All the polishing speeds shown in Table 1 are indicated in terms of the thickness of the object polished per unit time when polishing was performed under the conditions shown below. The thickness of the object polished per unit time can be calculated by dividing the difference between the thickness of the object before polishing and the thickness of the object after polishing, measured using an optical film thickness measuring instrument “VM-2030”, manufactured by Dainippon Screen Mfg. Co., Ltd., by the polishing time. The object to be polished when the polishing speed for polycrystalline silicon is measured is an 8-inch silicon wafer having a non-doped film of a thickness of 10,000 Å consisting of polycrystalline silicon. The object to be polished when the polishing speed for silicon dioxide is measured is an 8-inch silicon wafer having a TEOS film of a thickness of 10,000 Å consisting of silicon dioxide.

Polishing Conditions

Polisher: CMP equipment “CMS-200M” manufactured by Toshiba Machine Co., Ltd.

Polishing pad: “IC-1000 (A21)/Suba 400” manufactured by Rodel Inc.

Polishing pressure: 27.5 kPa (280 g/cm²)

Relative linear speed: 60 m/min

Polishing time: 30 seconds

The “Selection ratio” column of Table 1 shows the selection ratio, which is the ratio of the ability to polish silicon dioxide to the ability to polish polycrystalline silicon, of the polishing compositions of Examples 1 to 25. The selection ratio can be calculated by dividing the polishing speed for polycrystalline silicon by the polishing speed for silicon dioxide.

TABLE 1

| | | |
|---|---|---|
| Water-soluble | Polishing speed | |
| amine | (Å/min) | Selection |

| | Type | wt % | poly-Si | SiO₂ | ratio |
|---|---|---|---|---|---|
| Ex. 1 | TETA | 0.001 | 1,534 | 12 | 128 |
| Ex. 2 | TETA | 0.005 | 4,793 | 12 | 399 |
| Ex. 3 | TETA | 0.01 | 6,849 | 12 | 571 |
| Ex. 4 | TETA | 0.05 | 9,065 | 11 | 824 |
| Ex. 5 | TETA | 0.1 | 10,544 | 10 | 1,054 |
| Ex. 6 | TETA | 0.5 | 11,884 | 10 | 1,188 |
| Ex. 7 | TETA | 1.0 | 12,224 | 10 | 1,222 |
| Ex. 8 | TETA | 3.0 | 12,344 | 10 | 1,234 |
| Ex. 9 | TETA | 5.0 | 12,581 | 9 | 1,398 |
| Ex. 10 | TETA | 7.0 | 12,566 | 9 | 1,396 |
| Ex. 11 | TETA | 10.0 | 9,558 | 8 | 1,369 |
| Ex. 12 | TEPA | 0.001 | 1,236 | 12 | 103 |
| Ex. 13 | TEPA | 0.005 | 3,752 | 12 | 313 |
| Ex. 14 | TEPA | 0.01 | 5,961 | 12 | 497 |
| Ex. 15 | TEPA | 0.05 | 7,579 | 12 | 632 |
| Ex. 16 | TEPA | 0.1 | 8,388 | 11 | 763 |
| Ex. 17 | TEPA | 0.5 | 9,442 | 11 | 858 |
| Ex. 18 | TEPA | 1.0 | 9,558 | 10 | 956 |
| Ex. 19 | TEPA | 3.0 | 9,725 | 10 | 973 |
| Ex. 20 | TEPA | 5.0 | 9,996 | 9 | 1,111 |
| Ex. 21 | TEPA | 7.0 | 10,038 | 8 | 1,254 |
| Ex. 22 | TEPA | 10.0 | 9,812 | 8 | 1,227 |
| Ex. 23 | TETA | 0.1 | 10,724 | 10 | 1,072 |
| | TEPA | 0.1 | | | |
| Ex. 24 | TETA | 0.1 | 11,153 | 10 | 1,115 |
| | TEPA | 1.0 | | | |
| Ex. 25 | TETA | 1.0 | 12,284 | 10 | 1,228 |
| | TEPA | 1.0 | | | |

As Table 1 shows, all the polishing compositions of Examples 1 to 25 had the ability to polish polycrystalline silicon much higher than the ability to polish silicon dioxide, and the selection ratios thereof were 100 or more. No flaws due to polishing nor adhered substances were observed on the surface of each silicon wafer after polishing.

### EXAMPLES 26 TO 32

When the above-described polishing speeds for polishing polycrystalline silicon and silicon dioxide were measured using the polishing composition of Example 6, the polishing pressures and the relative linear speeds were changed. The polishing speeds were then measured, and the selection ratios calculated from the polishing speeds, which are shown in Table 2, together with the changed polishing pressures and relative linear speeds.

TABLE 2

| | | Relative | | | |
|---|---|---|---|---|---|
| | Polishing | linear | Polishing speed | | |
| | pressure | speed | (Å/min) | | Selection |
| | (kPa) | (m/min) | poly-Si | Sio₂ | ratio |
| Ex. 26 | 13.7 | 60 | 8,688 | 9 | 965 |
| Ex. 27 | 27.5 | 60 | 12,224 | 10 | 1,222 |
| Ex. 28 | 41.2 | 60 | 15,078 | 11 | 1,371 |
| Ex. 29 | 54.9 | 60 | 17,976 | 14 | 1,284 |
| Ex. 30 | 27.5 | 30 | 9,818 | 10 | 982 |
| Ex. 31 | 27.5 | 80 | 14,054 | 11 | 1,278 |
| Ex. 32 | 27.5 | 100 | 15,569 | 12 | 1,297 |

As Table 2 shows, the properties of the polishing composition of Example 6, which had the ability to polish polycrystalline silicon much higher than the ability to polish silicon dioxide, did not change even after polishing pressures and relative linear speeds had been changed. No flaws due to polishing nor adhered substances were observed on the surface of each silicon wafer after polishing.

### COMPARATIVE EXAMPLES 1

In Comparative Example 1, a polishing composition consisting of only colloidal silica and water was prepared. The colloidal silica in this polishing composition had an average particle diameter, calculated from the specific surface area measured by the BET method, of 90 nm. The content of the colloidal silica in the polishing composition was 20.0% by weight.

### COMPARATIVE EXAMPLES 2

In Comparative Example 2, a polishing composition containing fumed silica and water, whose pH was adjusted to 11.0 by an aqueous solution of potassium hydroxide, was prepared. The fumed silica in this polishing composition had an average particle diameter, calculated from the specific surface area measured by the BET method, of 40 nm. The content of the fumed silica in the polishing composition was 12.5% by weight.

### COMPARATIVE EXAMPLES 3

In Comparative Example 3, a polishing composition containing TETA, colloidal silica, and water was prepared. The colloidal silica in this polishing composition had an average particle diameter, calculated from the specific surface area measured by the BET method, of 35 nm. The content of the colloidal silica in the polishing composition was 1.0% by weight, and the content of TETA was 0.4% by weight.

### COMPARATIVE EXAMPLES 4

In Comparative Example 4, a polishing composition containing tetramethyl ammonium hydroxide, colloidal silica, and water was prepared. The colloidal silica in this polishing composition had an average particle diameter, calculated from the specific surface area measured by the BET method, of 35 nm. The content of the colloidal silica in the polishing composition was 1.7% by weight, and the content of tetramethyl ammonium hydroxide was 0.3% by weight.

### COMPARATIVE EXAMPLES 5

In Comparative Example 5, a polishing composition consisting of only tetramethyl ammonium hydroxide and water was prepared. The content of tetramethyl ammonium hydroxide was 0.3% by weight.

### COMPARATIVE EXAMPLES 6

In Comparative Example 6, a polishing composition consisting of DL-malic acid, benzotriazole, methanol, ammonium polyacrylate, hydrogen peroxide, and water was prepared. The polishing composition was prepared by dissolving 0.15 parts by weight of DL-malic acid in 70 parts by weight of water, and further dissolving 0.2 parts by weight of benzotriazole, 0.8 parts by weight of methanol, 0.01 parts by weight of ammonium polyacrylate, and 33.2 parts by weight of a 30 wt % aqueous hydrogen peroxide. This polishing composition is conventionally used for polishing copper films, and contains no solid components.

The results of obtained polishing speed and selection ratios using the polishing compositions of Comparative Examples 1 to 6 are shown in Table 3.

TABLE 3

Polishing speed
(Å/min)

| | Poly-Si | SiO₂ | Selection ratio |
|---|---|---|---|
| C. Ex. 1 | 1,410 | 851 | 1.66 |
| C. Ex. 2 | 6,856 | 4,422 | 1.55 |
| C. Ex. 3 | 12,368 | 24 | 515 |
| C. Ex. 4 | 7,611 | 21 | 362 |
| C. Ex. 5 | 877 | 18 | 54.3 |
| C. Ex. 6 | 108 | 17 | 6.35 |

As Table 3 shows, the polishing compositions of Comparative Examples 1 and 2 had the ability to polish silicon dioxide films substantially the same as the ability to polish polycrystalline silicon. Since the polishing compositions of Comparative Examples 1 to 4 contained solid components, flaws due to polishing and adhered substances were observed on the surface of each silicon wafer after polishing. The polishing compositions of Comparative Examples 5 and 6 had the ability to polish polycrystalline silicon lower than the polishing compositions of Examples 1 to 25.

The present examples and embodiments are to be considered as illustrative and not restrictive and the invention is not to be limited to the details given herein, but may be modified within the scope and equivalence of the appended claims.

1. A polishing composition for polishing an object having a portion including silicon dioxide and a portion including polycrystalline silicon, the polishing composition consisting of a liquid component including water and water-soluble amine, and the water-soluble amine comprising at least one of triethylenetetramine and tetraethylenepentamine and is dissolved in the water.

2. The polishing composition according to claim 1, wherein the portion including silicon dioxide is an insulating film, and the portion including polycrystalline silicon is a conductive film, wherein the insulating film has a surface including a trench, and the conductive film is located on the insulating film and has an inner portion located inside the trench and an outer portion located outside the trench, where the polishing composition is for polishing the object to remove the outer portion of the conductive film.

3. The polishing composition according to claim 1, wherein the content of the water-soluble amine in the polishing composition is 0.001 to 10% by weight.

4. The polishing composition according to claim 1, wherein the content of water in the polishing composition is 90 to 99.998% by weight.

5. The polishing composition according to claim 1, wherein a selection ratio, which is the ratio of the ability to polish silicon dioxide to the ability to polish polycrystalline silicon, of the polishing composition is 100 or more.

6. A method for polishing an object having an insulating film including silicon dioxide and a conductive film including polycrystalline silicon, with the insulating film having a surface including a trench, and the conductive film being located on the insulating film and having an inner portion located inside the trench and an outer portion located outside the trench, the method comprising the steps of:
preparing a polishing composition, wherein the polishing composition consists of a liquid component including water and water-soluble amine, and wherein the water-soluble amine comprises at least one of triethylenetetramine and tetraethylenepentamine and is dissolved in the water; and
polishing the object using the polishing composition to remove the outer portion of the conductive film.

7. The method according to claim 6, wherein the step of polishing the object using the polishing composition to remove the outer portion of the conductive film, includes compressing the object and a polishing pad against one another, and rotating the object and the polishing pad in directions opposite to each other while supplying the polishing composition to the polishing pad, wherein the pressure for compressing the object and the polishing pad against one another is 3.5 to 58 kPa.

8. The method according to claim 6, wherein the step of polishing the object using the polishing composition to remove the outer portion of the conductive film, includes compressing the object and a polishing pad against one another, and rotating the object and the polishing pad in directions opposite to each other while supplying the polishing composition to the polishing pad, wherein the relative linear speed between the object and the polishing pad during polishing is 30 to 100 m/min.

9. The method according to claim 6, wherein the step of polishing the object using the polishing composition to remove the outer portion of the conductive film comprises the sub-steps of:
removing part of the outer portion without using said polishing composition; and
polishing the object using said polishing composition to remove the remaining part of the outer portion.

10. The method according to claim 9, wherein the sub-step of removing part of the outer portion without using said polishing composition comprises removing silicon dioxide, which is formed by oxidation of polycrystalline silicon, on the surface of the conductive film.

11. The method according to claim 10, wherein said removing silicon dioxide is performed by dissolving the silicon dioxide using hydrofluoric acid.

12. A method for manufacturing a semiconductor device, the method comprising the steps of:
preparing a polishing composition, wherein the polishing composition consists of a liquid component including water and water-soluble amine, and wherein the water-soluble amine comprises at least one of triethylenetetramine and tetraethylenepentamine and is dissolved in the water;
preparing a semiconductor substrate having an insulating film including silicon dioxide;
forming a trench on the surface of the insulating film;
forming a conductive film including polycrystalline silicon on the insulating film to prepare an object having the insulating film and the conductive film, with the conductive film located on the insulating film and having an inner portion located inside the trench and an outer portion located outside the trench; and
polishing the object using the polishing composition to remove the outer portion of the conductive film.
